(19) United States
(12) Patent Application Publication
(10) Pub. No.: US 2005/0123838 A1
(43) Pub. Date: Jun. 9, 2005

(54) Clear field annular type phase shifting mask

(76) Inventors: Chung-Hsing Chang, Chu-Bei City (TW); C. H. Lin, Hsin-Chu (TW); Chung-Kuang Chen, Chung-Li City (TW)

Correspondence Address: DUANE MORRIS, LLP;IP DEPARTMENT, ONE LIBERTY PLACE, PHILADELPHIA, PA, 19103-7396, US

(21) Appl. No.: 10/730,533

(22) Filed: Dec. 8, 2003

(51) Int. Cl. G03F 9/00

(52) U.S. Cl. 430/5; 430/311

(57) ABSTRACT

A mask comprises a mask substrate and at least one annular equal line space phase shifting pattern on said mask substrate to produce an opaque region on a semiconductor substrate. A method of manufacturing a mask comprises providing a mask substrate; forming a layer of resist material on said substrate; patterning at least one annular equal line space phase shifting pattern on said resist layer; patterning said pattern onto said mask substrate; removing a remaining portion of said resist layer. A method of transferring a pattern onto a semiconductor substrate comprises illuminating a mask comprising at least one annular equal line space phase shifting pattern on the mask to produce an opaque region on a semiconductor substrate.

### FIELD OF THE INVENTION

The present invention relates to integrated circuit fabrication and more particularly to a phase shifting mask used in a photolithography process and a method of manufacturing therefor.

### DESCRIPTION OF RELATED ART

In the semiconductor industry, there is a continuing effort to increase device density by scaling the device size. Conventionally, to form an integrated circuit, a resist layer is formed on a wafer and is exposed to radiation through a photomask (“mask”). A mask typically comprises a substantially transparent base material such as quartz with an opaque layer having a desired pattern formed thereon. For example, chrome has long been used to make the opaque layer. When device features are reduced to a dimension below 1 micron, diffraction effects become significant. The blending of two diffraction patterns associated with features which are close to each other has an adverse effect on resolution, because portions of the resist layer underlying the opaque layer near the edges of features will be exposed.

To minimize effects of diffraction, various kind of phase shifting masks have been used. Typically, a phase shifting mask has a pattern in the opaque layer, corresponding to the pattern to be formed on the underlying resist. In addition, phase-shifters, which transmit the incident radiation and shift the phase of the radiation approximately 180 degrees, are added onto the mask reduce diffraction effects. Alternate aperture phase shifting masks are formed by adding phase-shifters over every other opening. In rim phase shifting masks, phase-shifters are added along or near the outer edges of features. The radiation transmitted through the phase-shifter destructively interferes with radiation transmitted through the feature, thereby reducing the intensity of radiation incident on the resist material underlying the opaque layer near a feature edge to in order to improve image resolution.

Such phase shifting masks, however, have limitations on their ability to pattern some features and are difficult to fabricate. When two features are placed in close proximity to one another, for example, in rim phase shifting masks, two phase-shifters associated with features which are close to each other would roughly merge into a wide rim resulting in over exposure of the region of resist material between two openings. Further, phase-shifters may be fabricated by a separate step from the formation of the pattern on the opaque layer. To improve resolution by destructive interference, the locations of the phase-shifters must be precisely correlated with the pattern on the opaque layer. For very small features, the alignment tolerance between the opaque layer with pattern and phase-shifters may exceed the capability of the process.

To resolve these problems, an attenuated phase-shifting mask (“AttPSM”) has been proposed. The AttPSM replaces the opaque layer (which is typically a layer of chrome about 0.1μ thick) with a “leaky” layer which transmits a reduced percentage of the incident radiation. For example, a very thin layer of chrome (approximately 300 angstroms) with approximately 10% transmittance could be used as the leaky layer. In addition, the leaky chrome layer shifts the phase of the transmitted radiation by a certain number of degrees, for example approximately 30 degrees, depending on the thickness and refractive index of the layer. To achieve the required 180 degrees phase shift between radiation transmitted through regions covered by the leaky chrome layer and regions of features, the features are also phase shifted a complementary angle by etching the mask or by placing a phase-shifting material in the regions of features.

Nonetheless, it is extremely difficult to deposit a thin layer of chrome with uniform thickness across the surface of the mask. Furthermore, physical characteristics such as refractive index fluctuate across the surface of the leaky chrome layer on the mask. The leaky chrome layer itself can not shift the phase of incident radiation 180 degrees. Additional processes needed to achieve this goal increase manufacturing cost and difficulty.

To overcome these difficulties, an embedded coating material which integrates the property of obtaining the required 180 degrees phase shift into the substrate coating layer which transmits a reduced percentage of the incident radiation, has been used. An embedded coating material such as molybdenum silicide (MoSiOₓN_{y}) is used to achieve AttPSM. However, molybdenum silicide only provides a low transmittance of about 8 percent. A phase shifting mask which can attain high transmittance and without employing an opaque layer such as chrome is needed.

### SUMMARY OF THE INVENTION

A mask comprises a mask substrate and at least one annular equal line space phase shifting pattern on said mask substrate to produce an opaque region on a semiconductor substrate. A method of manufacturing a mask comprises providing a mask substrate; forming a layer of resist material on said substrate; patterning at least one annular equal line space phase shifting pattern on said resist layer; patterning said pattern onto said mask substrate; removing a remaining portion of said resist layer. A method of transferring a pattern onto a semiconductor substrate comprises illuminating a mask comprising at least one annular equal line space phase shifting pattern on the mask to produce an opaque region on a semiconductor substrate.

### BRIEF DESCRIPTION OF THE DRAWINGS

A more complete understanding of the present invention can be obtained by reference to the detailed description of embodiments in conjunction with the accompanying drawing, in which:

FIG. 1A illustrates a top view of a mask with an annular equal line space phase shifting pattern;

FIG. 1B illustrates a cross sectional view of the mask shown in FIG. 1A;

FIG. 2A illustrates a top view of a mask with another embodiment of annular equal line space phase shifting pattern;

FIG. 2B. illustrates a cross sectional view of the mask shown in FIG. 2A;

FIGS. 3A-3H illustrate processes of manufacturing a mask shown in FIG. 1A;

FIG. 4 illustrates an off-axis illumination of a mask during a photolithographic process;

FIG. 5 illustrates a circuit pattern to be formed in a semiconductor substrate;

FIG. 6 illustrates a corresponding pattern on a phase-shifting mask to form the circuit pattern shown in FIG. 5.

### DETAILED DESCRIPTION OF THE INVENTION

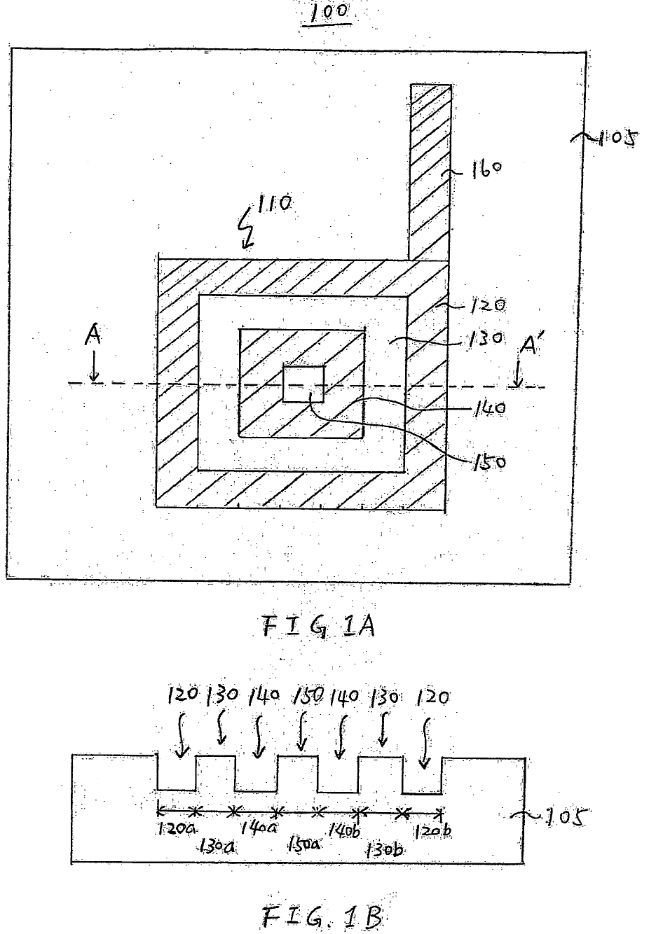

As shown in FIG. 1A, an exemplary embodiment is a mask 100 containing an annular equal line space phase shifting pattern 110 and other features, such as a line 160, on a mask substrate 105. In this embodiment, the mask substrate 105 is transparent to incident radiation because no chrome is used to form the pattern 110 and other features. The incident radiation can be, for example, I-line (365 nm) or deep ultraviolet radiation (193 nm). A phase difference may be generated if the incident radiation travel paths of different length in the mask substrate.

The pattern 110 is an annular equal line space phase shifting structure that comprises annular rings 120, 130, 140, and a central portion 150. The outermost annular ring 120 has a phase shift of approximately 180 degrees from the mask substrate 105. The inner annular ring 130 has a phase shift of approximately 180 degrees from the outermost ring 120. Likewise, the innermost annular ring 140 has a phase shift of approximately 180 degrees from the inner annular ring 130 and the central portion 150 has a phase shift of approximately 180 degrees from the innermost annular ring 140. That is to say, phases of adjacent annular rings shift 180 degrees and phases of alternate annular rings are the same. In summary, annular rings 120 and 140 have the same phase, for example π (180 degrees). The mask substrate 105, annular ring 130, and the central portion 150 have the same phase, for example 0, that is 180 degrees different from that of annular rings 120 and 140.

Referring to FIG. 1B, which is a cross sectional view from line AA′ of FIG. 1, the widths 120a and 120b of the annular ring 120, the widths 130a and 130b of the annular ring 130, the widths 140a and 140b of the annular ring 140, and the width 150a of the central portion 150 are approximately the same. Accordingly, the pattern 110 is characterized as an annular equal line space structure. Although pattern 110 is transparent to an incident radiations, it creates a corresponding dark region on a semiconductor substrate through a known photolithographic process, resulting from the diffraction of its annular equal line space phase shifting structure.

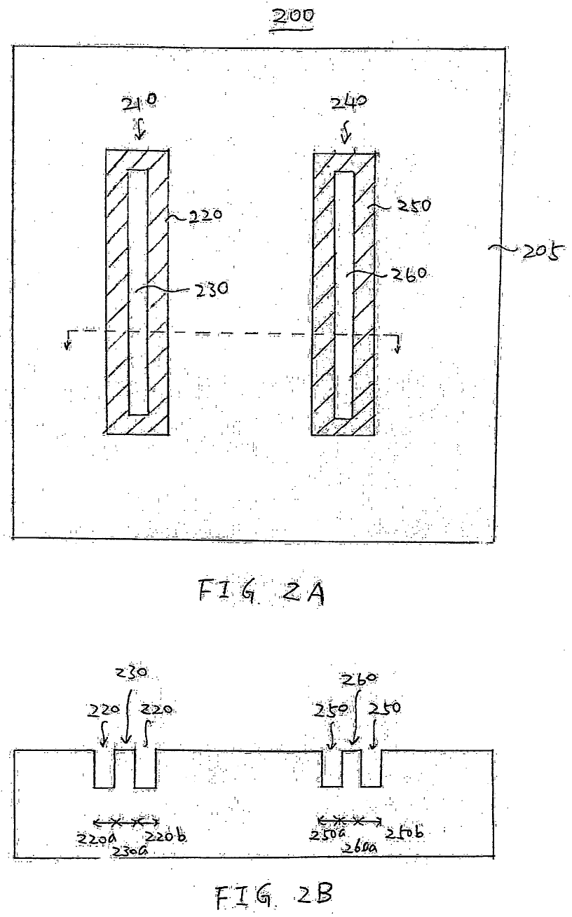

In other embodiments, number of annular rings may vary; as long as an outermost annular ring has a phase shift of approximately 180 degrees from the mask substrate, each inner annular ring has a phase shift of approximately 180 degrees from its outer adjacent annular ring, and the central portion has a phase shift of approximately 180 degrees from its adjacent innermost ring. In an alternate embodiment as shown in FIGS. 2A and 2B, patterns 210 and 240 respectively have only one annular ring and a central portion. The pattern 210 has an annular ring 220 and a central portion 230. The pattern 240 also has an annular ring 250 and a central portion 260. The annular rings 220 and 250 have a phase shift of approximately 180 degrees from that of a mask substrate 205 and of the central portion 230 and 260. In addition, to form equal line space structure, the widths 220a and 220b of the annular ring 220, and the width 230a of the central portion 230 are the same; the widths 250a and 250b of the annular ring 250 is the same as the width 260a of the central portion 260.

The pitch (Pcs) of critical dimension (two times of a critical dimension) of a pattern that can be exposed on a semiconductor substrate under a specific environment, is calculated as follows:
Pcs=λ/((1+δ)NA)
where Pcs is the pitch of critical dimension; λ is the wavelength of an incident radiation for patterning a semiconductor substrate; δ is the degree of coherence; and NA is the numerical aperture of a photolithography equipment.

The pitch (Pm) on a mask substrate is N times of the corresponding pitch (Ps) on a semiconductor substrate where N can be an integer equal to or larger than one. For example, a four times (4×) mask is used in a stepper for photolithography processes, i.e. Pm=4Ps. In order to form a large opaque region on a semiconductor substrate, there is no requirement of minimum mask pitch (Pm) for the annular equal line space phase shifting pattern as long as photolithography technology allows. As a result, a mask pitch (Pm) smaller than the corresponding critical dimension pitch on a semiconductor substrate (N×Pcs, for example 4 Pcs) can result to a large opaque region on a semiconductor substrate. However, the mask pitch (Pm) of an annular equal line space phase shifting pattern has to be smaller than two times of the corresponding critical dimension pitch on a semiconductor substrate (N×2 Pcs, for example 8 Pcs), in order to form a large opaque region on a semiconductor substrate. That is to say, 0<Pm<N×2 Pcs.

Those skilled in the art can calculate an appropriate mask pitch (Pm), such as 2 times of 120a, in order for an annular equal line space structure, such as pattern 110, to produce a corresponding dark region on a semiconductor substrate. In one embodiment using a 4× stepper, the mask pitch (Pm) of 960 nm, which corresponds to pitch (Ps) of 240 nm on the semiconductor substrate, is used in an equal line space structure to generate a corresponding dark region on a semiconductor substrate under the photolithography environment. For example, where the wavelength (λ) of an incident radiation is 248 nm; the degree of coherence (δ) is 0.85; the numerical aperture (NA) is 0.75; and off axis illumination is applied, the mask pitch (Pm) is 960 nm. Accordingly, for a specific pattern on a mask substrate that intends to generate a corresponding dark region on a semiconductor substrate, number of annular rings needed can be determined by the appropriate mask pitch (Pm).

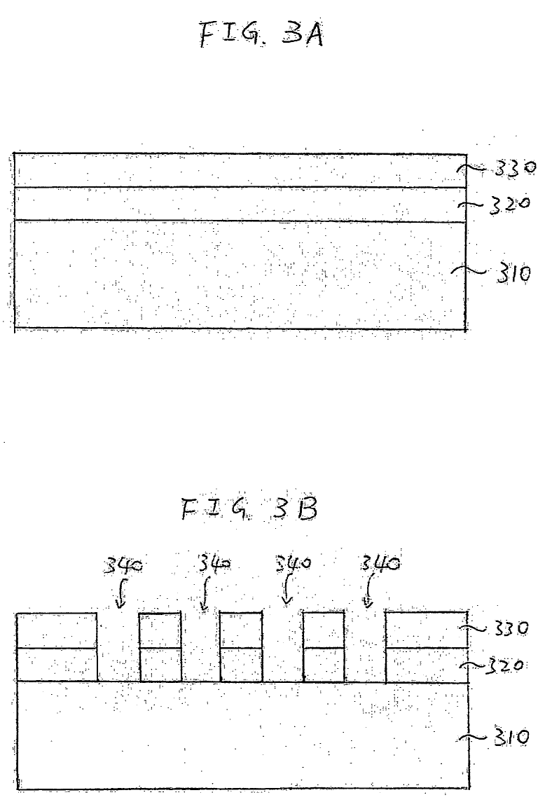

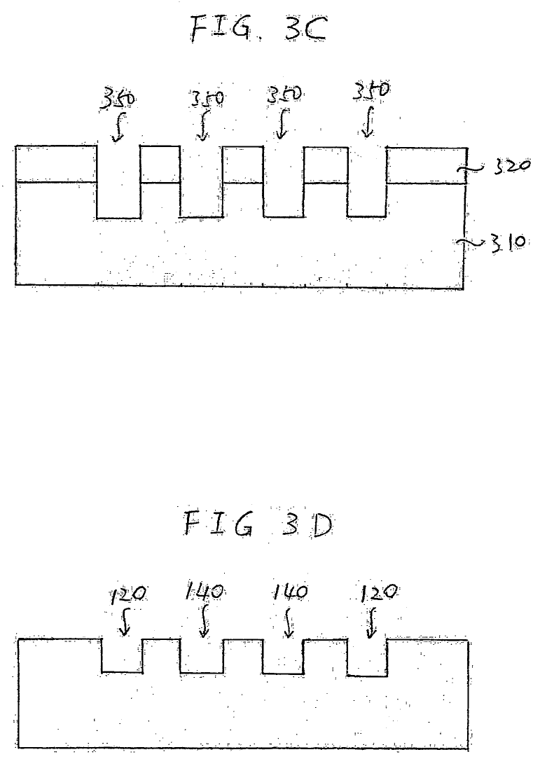

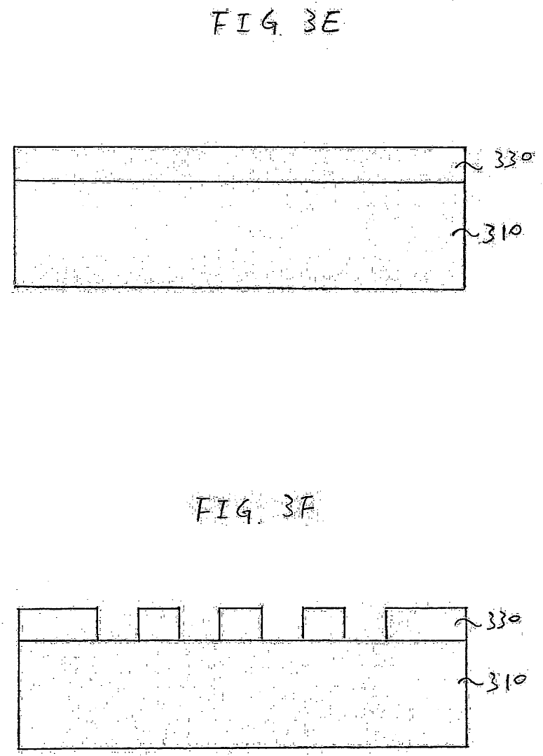

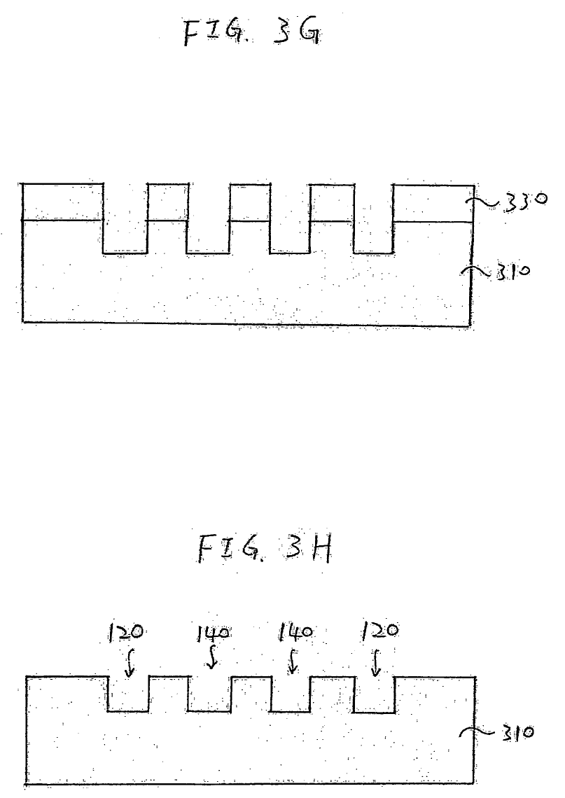

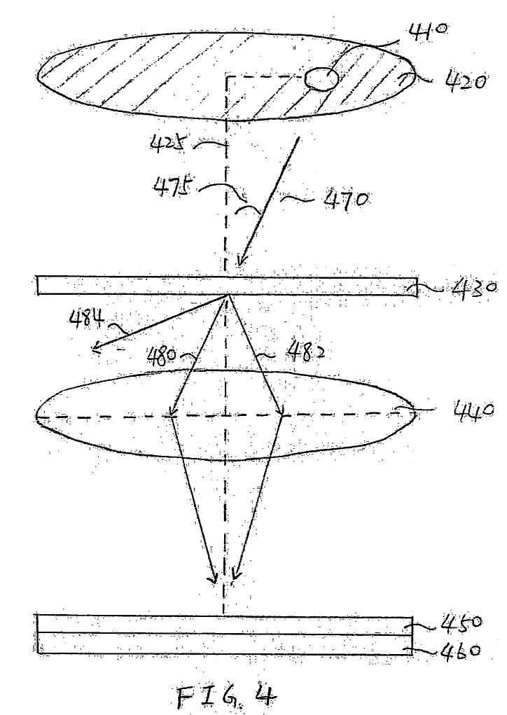

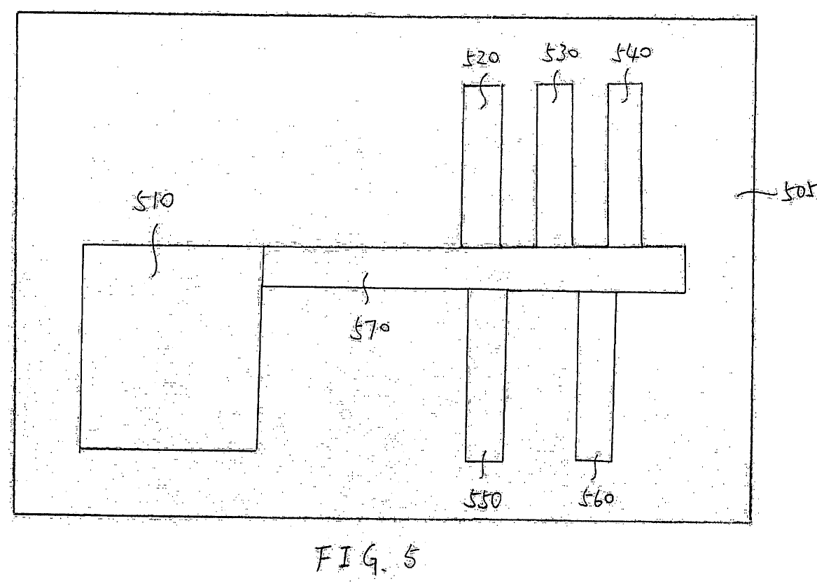

As illustrated in FIG. 3A-3D, an exemplary embodiment of manufacturing the mask 100 is to form a conductive layer 320 and a resist layer 330 above a mask substrate 310 and to pattern an annular equal line space phase shifting pattern 110 onto the mask by photolithography and etching. In FIG. 3A, the layer of conductive material 320 such as chrome is formed over the mask substrate 310, such as a quartz. Chemical vapor deposition can be used to form the chrome layer 320. A layer of resist material 330 is formed over the chrome layer 320, for example, by sputtering the resist material over the chrome layer 320. An exposure source (not shown), for example a laser with a wavelength of 364 nm (I-line) or electron beam, is used to transfer the desired pattern 110 onto the resist layer 330. Exposed portions of the resist layer 330 and their underlying portions of the chrome layer 320—for example, the portions corresponding to annular rings 120 and 140 in FIG. 1A—are etched away. In some embodiments, a wet etching or an anisotropic dry etching can be used. After etching, as illustrated in FIG. 3B, trench-like shapes 340 are formed. The remaining part of the resist layer is then removed by for example ashing. The pattern left on the chrome layer 320 as shown in FIG. 3C is used to etch the mask substrate 310 to a predetermined thickness. The predetermined thickness is designed to create a phase difference of 180 degrees as to an incident radiation employed to pattern a semiconductor substrate, such as a silicon wafer. After etching the mask substrate 310, trench-like shapes 350 are formed as shown in FIG. 3C. The remaining portion of the chrome layer 320 is then removed. As shown in FIG. 3D, a phase shifting mask with the pattern 110 is fabricated. Trench-like shapes 350 correspond to the cross sectional view of annular rings 120 and 140 in FIG. 1A. FIG. 3E-3H demonstrate another embodiment of manufacturing the mask 100. When a radiation source is used for exposure such as a laser writer with a wave length of 193 nm, the resist layer 330 is formed over the mask substrate 310 without a conductive layer. The annular equal line space phase shifting pattern 110 is formed on the resist layer 330 and then transfer onto the mask substrate 310 by etching.

In another embodiment, a layer of phase shifting material can be formed on the mask substrate to produce a phase difference of approximately 180 degrees in order to generate an annular equal line space phase shifting pattern.

As shown in FIG. 4, a mask 430 with an annular equal line space phase shifting pattern can be illuminated to produce a corresponding dark region on a resist layer 450 in order to pattern the underlying semiconductor substrate 460. In one embodiment, a single point off-axis illumination (OAI) is used in a photolithographic process. Light from a radiation resource is blocked by 420 and can only pass through an aperture 410 to form incident radiation at an angle 475 away from an axis 425. In other embodiments of off-axis illumination, an annular or quadrupole aperture can be employed to illuminate the mask. By using an off-axis illumination, both the resolution and the depth of focus (“DOE”) of a photolithographic process are increased. As a result of using an off-axis illumination, normally after an incident light 470 passes through a feature other than an annular equal line space phase shifting pattern on the mask 430, only 0 order 480 and +1 order 482 of the diffraction resulting from an incident radiation 470 are collected by a projection lens 440 to form an image on a resist layer 450 which is deposited on a semiconductor substrate 460.

However, when an incident radiation 470 passes an annular equal line space phase shifting pattern where N×Pcs<Pm<N×2 Pcs, 0 order 480 of the diffraction disappears and only +1 order 482 of the diffraction enters a projection lens 440 to form an image. Because the intensity of +1 order 482 of the diffraction alone is much lower than a threshold exposure intensity, the portion of resist underlying an annular equal line space phase shifting pattern is not exposed. In another embodiment, when a mask pitch (Pm) is smaller than the corresponding critical dimension pitch on a semiconductor substrate (N×Pcs, for example 4 Pcs), i.e. Pm<N×Pcs, not only 0 order of the diffraction disappears but +1 order of the diffraction is also not collected by a projection lens. As a result, a large opaque region on a semiconductor substrate can be obtained. An opaque region that corresponds to the annular equal line space phase shifting pattern is then formed on the resist layer 450 and further transferred to the semiconductor substrate 460. Without employing an annular equal line space phase shifting pattern, a large feature such as a pad or an interconnect would be exposed to a ring-like shape with a hollow inside rather than a solid shape that the feature is designed to be. Thus, when a sufficiently large feature, depending on the photolithography environment, begins to be exposed as a hollow ring rather than a solid dark region on a semiconductor substrate, an equal line space phase shifting pattern can be applied to the large interconnect to improve the result of exposure.

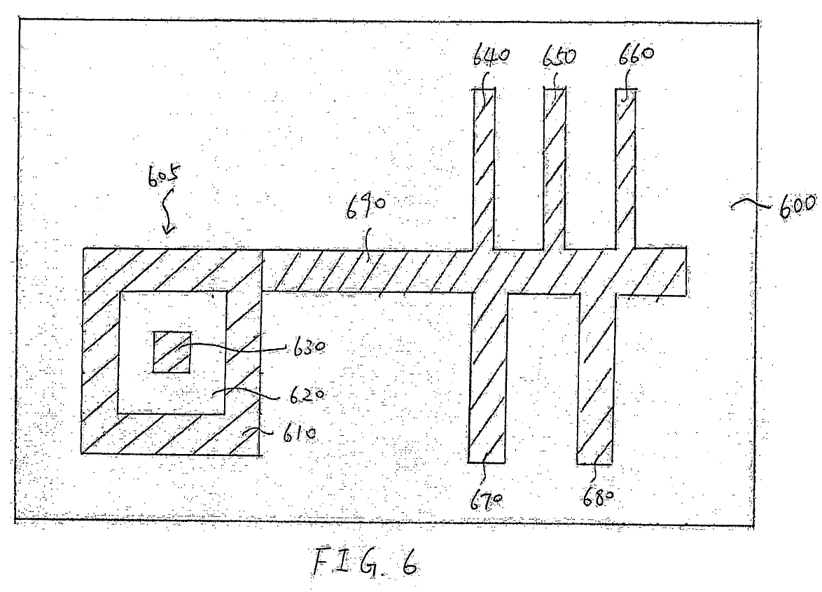

As shown in FIG. 5, an integrated circuit design on a semiconductor substrate usually contains a larger interconnect area 510 and thinner interconnect lines 520 to 570. A phase shifting mask capable of transferring a pattern containing both large opaque areas 510 and features with critical small dimension 520 to 570 is necessary. As mentioned above, a chromeless phase shifting mask with an annular equal line space phase shifting pattern thereon can be employed to transfer an opaque region onto a semiconductor substrate such as a wafer. Thus, to form a larger interconnect area 510 on a wafer, an annular equal line space phase shifting pattern 605 on a mask comprising annular rings 610, 620 and a central portion 630 as shown in FIG. 6 is used. The annular ring 610 and the central portion 630 are at the same phase, which is approximately 180 degrees different from that of the annular ring 620 and of the mask substrate 600.

On the other hand, in order to form equal-line-space interconnect lines 520, 530, and 540 on a semiconductor substrate such as a wafer, corresponding lines 640, 650, and 660 on a mask have to be positively biased. Lines 640, 650, and 660 are of a phase approximately 180 degrees different from the mask substrate 600.

Although the invention has been described in terms of exemplary embodiments, it is not limited thereto. Rather, the appended Claims should be construed broadly, to include other variants and embodiments of the invention, which may be made by those skilled in the art without departing from the scope and range of equivalents of the invention.

1. A mask comprising:
a mask substrate, and
at least one annular equal line space phase shifting pattern on said mask substrate to produce an opaque region on a semiconductor substrate.

2. The mask of claim 1, wherein said pattern comprises an annular ring and a central portion.

3. The mask of claim 2, wherein said annular ring has a phase shift of approximately 180 degrees from said mask substrate and said central portion.

4. The mask of claim 1, wherein said pattern comprises a plurality of annular rings and a central portion.

5. The mask of claim 4, wherein an outermost annular ring has a phase shift of approximately 180 degrees from said mask substrate and an adjacent inner annular ring, each inner annular ring having a phase shift of approximately 180 degrees from its outer adjacent annular ring, and said central portion having a phase shift of approximately 180 degrees from an innermost ring.

6. The mask of claim 1, wherein said mask substrate comprises quartz.

7. The mask of claim 1, wherein said pattern is substantially transparent to an incident radiation for photomasking.

8. The mask of claim 1, where a mask pitch of said pattern is smaller than two times of a corresponding critical dimension pitch on said semiconductor substrate.

9. A method of manufacturing a mask, comprising:
providing a mask substrate;
forming a layer of resist material over said mask substrate;
patterning at least one annular equal line space phase shifting pattern on said resist layer;
patterning said pattern onto said mask substrate;
removing a remaining portion of said resist layer.

10. A method of manufacturing a mask, comprising:
providing a mask substrate;
forming a layer of conductive material over said mask substrate;
forming a layer of resist material over said conductive layer;
patterning at least one annular equal line space phase shifting pattern on said resist layer;
patterning said pattern onto said conductive layer;
removing a remaining portion of said resist layer;
patterning said pattern onto said mask substrate; and
removing a remaining portion of said conductive layer.

11. The method of claim 10, wherein said mask substrate comprises quartz.

12. The method of claim 10, wherein said layer of conductive material comprises chrome.

13. The method of claim 10, wherein said pattern comprises an annular ring and a central portion.

14. The method of claim 10, wherein said pattern comprises a plurality of annular rings and a central portion

15. The method of claim 10, wherein said pattern is formed on said mask substrate by etching said mask substrate.

16. The method of claim 10, wherein said pattern is formed on said mask substrate by disposing phase shifting material on said mask substrate.

17. A method of transferring a pattern onto a semiconductor substrate, comprising:
illuminating a mask comprising at least one annular equal line space phase shifting pattern on said mask to produce an opaque region on said semiconductor substrate.

18. The method of claim 17, wherein off-axis illumination is used for illuminating said mask.

19. The method of claim 18, wherein off-axis illumination can be a single point, dipole, quadrupole, or annular type off-axis illumination.

20. The method of claim 18 wherein deep ultra radiation is used as a radiation resource to illuminate said mask.

21. The method of claim 18 wherein said semiconductor substrate comprises silicon.

22. A semiconductor wafer manufactured by the method of claim 18.
